(19) United States
(12) Patent Application Publication
(10) Pub. No.: US 2006/0228850 A1
(43) Pub. Date: Oct. 12, 2006

(54) Pattern loading effect reduction for selective epitaxial growth

(76) Inventors: Pang-Yen Tsai, Jhu-bei City (TW); Chih-Chien Chang, Miow-Li County (TW); Indira Yang, Chupei City (TW); Tze-Liang Lee, Hsinchu (TW); Shih-Chang Chen, Hsin-Chu (TW)

Correspondence Address: SLATER & MATSIL, L.L.P., 17950 PRESTON ROAD, SUITE 1000, DALLAS, TX, 75252, US

(21) Appl. No.: 11/100,053

(22) Filed: Apr. 6, 2005

(51) Int. Cl. H01L 21/8238; H01L 21/76

(52) U.S. Cl. 438/219; 438/230; 438/413

(57) ABSTRACT

A method of reducing the pattern-loading effect for selective epitaxial growth. The method includes the steps of: forming a mask layer over a substrate; forming an isolation region in the substrate isolating an active region and a dummy active region; removing at least a portion of the mask layer in the active region and thus forming a first opening, the substrate being exposed through the first opening; removing at least a portion of the mask layer in the dummy active region and thus forming a second opening, the substrate being exposed through the second opening; and performing selective epitaxial growth simultaneously on the substrate in the first opening and second openings. By introducing the second opening wherein epitaxial growth occurs, the pattern density is more uniform and thus the pattern-loading effect is reduced.

### TECHNICAL FIELD

This invention relates generally to semiconductor integrated circuits, and more specifically to selective epitaxial processes for semiconductor integrated circuits.

### BACKGROUND

In order to improve semiconductor integrated device properties, the selective epitaxial growth (SEG) process, also known as selective EPI, was developed. The SEG process has been widely used in strained silicon, elevated source and drain and shallow junction formation.

As is generally known in the art, in the SEG process, single crystal semiconductor material such as silicon or silicon germanium is grown on exposed regions of a semiconductor layer and is not grown on insulating layers such as oxide layers and nitride layers. As a result, the SEG process is different from a general chemical vapor deposition (CVD) process and therefore, unique problems have arisen in the development of the SEG process. One of the problems is the pattern-loading effect, which occurs due to a difference in pattern density, and which degrades the uniformity of pattern sizes. The “pattern loading effect” pertains to a phenomenon occurring upon simultaneous epitaxial growth in a pattern of a higher density and a pattern of a lower density. Due to a difference in growth rate of a film from one location to another, the amount of growth becomes locally dense or sparse depending on the local pattern density, and this causes a non-uniformity in the thickness of the film. Large variations in effective pattern density have been shown to result in significant and undesirable film thickness variation. For example, isolated active regions that are surrounded by regions having a large area ratio of dielectrics (meaning less surface area for the epitaxial growth) would have faster growth of the EPI layer than dense active regions. In addition, the composition of the EPI layer at the isolated active regions is also different from that of densely packed active regions. Particularly, this non-uniformity makes the device formation process hard to control and device performance may be adversely affected.

The pattern loading effect can be reduced by adjusting epitaxy parameters, such as reducing the process pressure or adjusting reaction gas flow rates. However, other EPI properties, such as composition, are also impacted by the changes of the pressure and gas flow rate. Additionally, the amount of reduction of the loading effect using this method is not satisfactory.

To effectively counteract the pattern loading effect, a layout design step known as a dummy pattern is used, wherein the circuit layout is modified and dummy patterns are added to locations with low pattern density. For selective epitaxial growth, dummy patterns are formed in sparse pattern regions over dielectric material covering the regions. They are typically formed of materials similar to the material where growth is to occur. Selective epitaxial growth occurs on both desired regions and dummy pattern regions. The adding of dummy patterns helps in achieving more uniform pattern density across the wafer, thereby reducing pattern-loading effects. This method provides better results. However, additional process steps and thus higher costs are involved. Silicon dummy patterns have to be formed in selective locations to make the density of the silicon patterns uniform.

Therefore, there is the need for a low cost, effective method for reducing pattern-loading effects.

### SUMMARY OF THE INVENTION

The preferred embodiment of the present invention provides a method of reducing pattern loading effects for selective epitaxial growth.

In accordance with one aspect of the present invention, the method includes the steps of forming a mask layer over a substrate, forming an isolation region in the substrate isolating an active region and a dummy active region, removing at least a portion of the mask layer in the active region to form a first opening through which the substrate is exposed, removing at least a portion of the mask layer in the dummy active region to form a second opening through which the substrate is exposed, and performing selective epitaxial growth simultaneously on the exposed portions of the substrate in the first opening and second opening. By forming openings in the dummy active region, the selective epitaxial growth occurs in openings in the active region and the dummy active region. The pattern density is more uniform and thus the pattern-loading effect is reduced.

In accordance with another aspect of the present invention, additional openings can also be formed in the active region. The pattern uniformity within the active region can be improved and thus the overall pattern-loading effect is further reduced.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A through 9B illustrate cross sectional views of intermediate stages in the manufacture of preferred embodiments of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

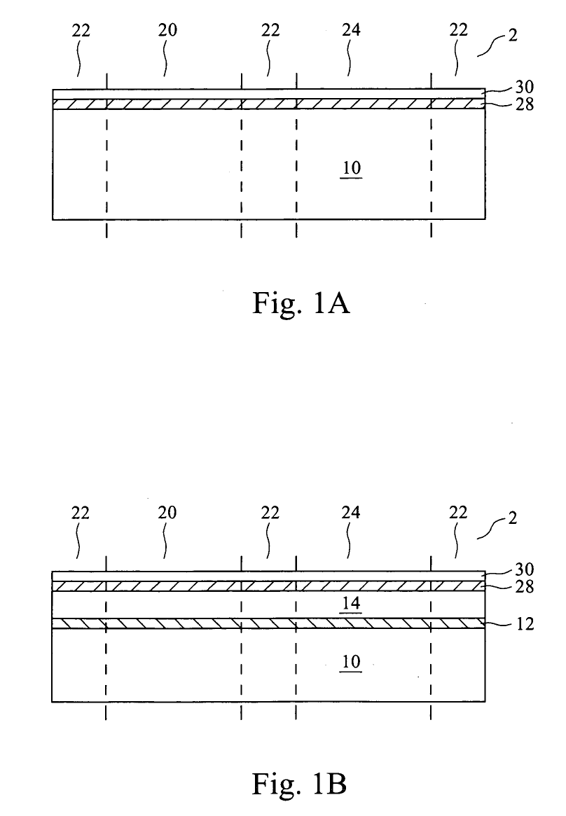

The cross sectional views of the intermediate stages in the manufacture of preferred embodiments are illustrated in FIGS. 1A through 9B, wherein like reference numbers are used to designate like elements throughout the various views and illustrative embodiments of the present invention. The preferred embodiments of the present invention use the selective growth of source/drain regions as an example. One skilled on the art will realize that the method discussed applies to selective epitaxial growth of other crystal components in integrated circuits as well.

FIGS. 1A and 1B illustrate cross sectional views of a portion of a chip 2. In the preferred embodiment shown in FIG. 1A, substrate 10 is a semiconductor. More preferably, substrate 10 is formed of silicon. In other embodiments, substrate 10 can be formed of other semiconductor or insulator materials comprising silicon, carbon, germanium, gallium, arsenic, nitrogen, aluminum, indium, and/or phosphorus. Substrate 10 may be in the form of single crystal or compound. In order to improve the performance of the device, substrate 10 is preferably strained. However, non-strained materials can also be used.

FIG. 1B illustrates a chip 2 having a silicon-on-insulator (SOI) structure. The SOI structure includes a thin buried insulating layer, or preferably buried oxide (BOX) 12 over a first substrate 10, and a second substrate 14 over the BOX 12. Box 12 is preferably a thermal oxide. The second substrate 14 is preferably doped silicon, although other materials, such as Ge, SiGe, SiGeC and their combinations can be used. The first substrate 10 and the second substrate 14 may comprise the same material or different materials.

For illustrative purposes, chip 2 is divided into three types of regions. Region 20 is an active region where active devices are formed. Regions 22 are isolation regions. They are used to isolate different regions and/or devices, and are formed of dielectric materials. Region 24 is a dummy active region that has neither active devices nor isolations formed therein.

An optional pad layer 28 and a mask layer 30 are formed over the top-most substrate (substrate 10 in FIG. 1A, or substrate 14 in FIG. 1B). Pad layer 28 is preferably a thin film formed through a thermal process. It is used to buffer substrate 10 and mask layer 30 so that less stress is generated. Pad layer 28 may also act as an etch stop layer for the subsequently formed mask layer 30. In the preferred embodiment, mask layer 30 is formed of silicon nitride using low-pressure chemical vapor deposition (LPCVD). In other embodiments, mask layer 30 is formed by thermal nitridation of silicon, plasma enhanced chemical vapor deposition (PECVD) or plasma anodic nitridation using nitrogen-hydrogen. It has a preferred thickness of between about 100 nm and about 200 nm.

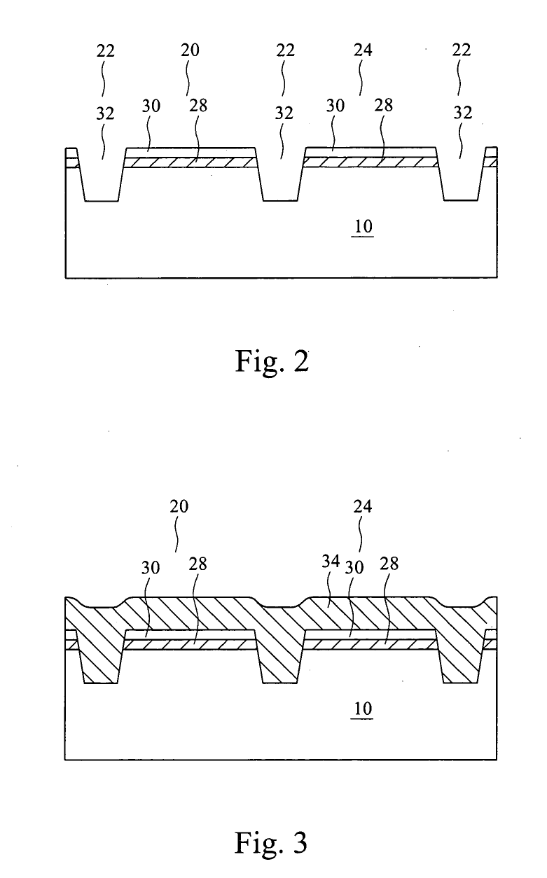

Trenches 32 are anisotropically formed in the isolation regions 22 by etching through mask layer 30 and extending into substrate 10. FIG. 2 illustrates the trenches 32 formed in the chip shown in FIG. 1A. In the embodiments shown in FIG. 1B, the trenches preferably reach the BOX 12 so that the subsequently formed devices are enclosed in dielectric materials and thus the leakage current is reduced.

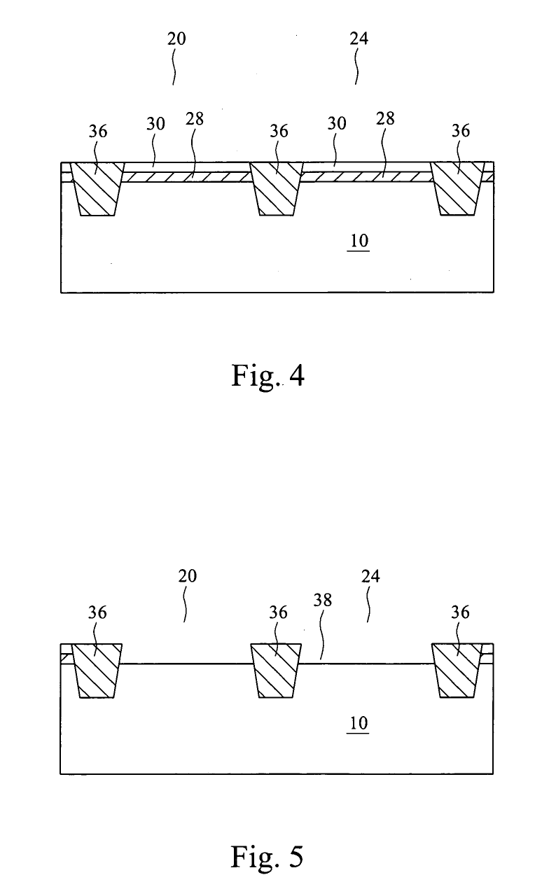

FIG. 3 illustrates the trenches 32 filled with a dielectric material 34. Preferably, the filling material is silicon oxide formed by high-density plasma (HDP). Other materials such as silicon oxynitride may also be used. A chemical mechanical polish (CMP) is performed to remove excess dielectric material 34, thus a structure as shown in FIG. 4 is formed. The remaining portion of dielectric material 34 forms shallow-trench-isolations (STI) 36.

FIG. 5 illustrates a selective etch removing at least a portion of the mask layer 30 and pad layer 28 in the active region 20 and dummy active region 24. Substrate 10 is exposed where mask layer 30 and pad layer 28 are removed. Devices are formed on the exposed substrate 10 in active region 20. For simplicity, the formation of a single device is illustrated. In actual practice, there may be multiple devices formed in the active region 20. If devices are formed in active regions and no device is formed in the dummy active region 24, then in the subsequent selective epitaxial growth of the source and drain regions, silicon substrate 10 has multiple portions exposed in the active region 20, while there is no exposed silicon substrate 10 in dummy active region 24. This will cause non-uniformity of the pattern density and thus pattern-loading effects will occur. Therefore, a portion of the mask layer 30 and pad layer 28 are removed in dummy active region 24, forming an opening 38. Silicon substrate 10 is exposed through the opening 38. The removal of the mask layer 30 and pad layer 28 in dummy active region 24 is preferably performed simultaneously with the removal of the same layers in active region 20. The selection of locations and areas of the openings 38 is a design decision, and the pattern density in the active region 20 has to be taken into consideration so that uniform pattern density on the chip can be achieved. Although layers 28 and 30 are shown as completely removed in FIG. 5, it may be preferred that only portions of layers 28 and 30 are removed, and dummy patterns will be formed in the removed portions.

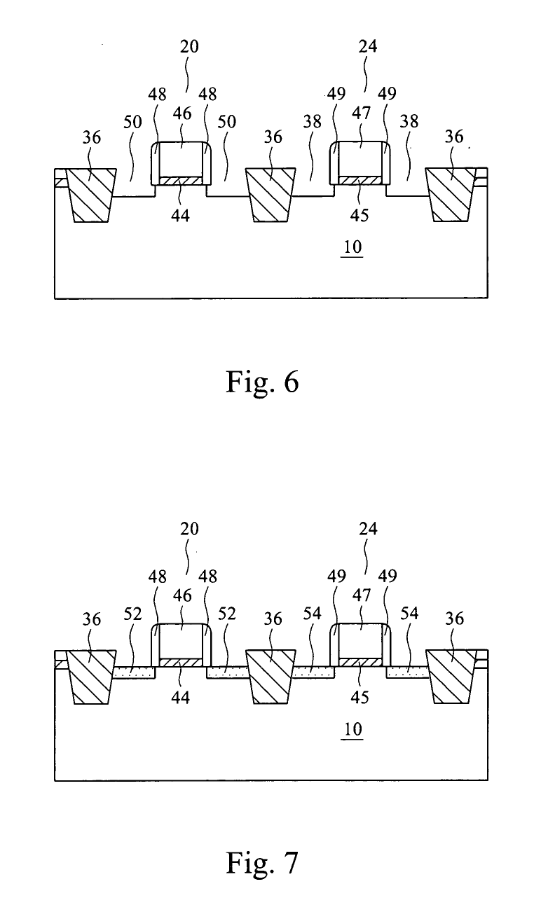

As shown in FIG. 6, a gate dielectric 44 and a gate electrode 46 are formed on the substrate 10 in active region 20. As known in the art, to form the gate dielectric 44 and gate electrode 46, a gate dielectric layer may be formed by thermal oxidation or other methods. A gate electrode layer is then formed on the gate dielectric layer. The Gate electrode layer is preferably polysilicon, although it may also be metal or metal compound comprising titanium, tungsten, cobalt, aluminum, nickel or combinations thereof. The gate dielectric layer and gate electrode layer are then patterned to form the gate dielectric 44 and gate electrode 46. The substrate 10 under gate dielectric 44 eventually becomes a channel region of the resulting transistor. A pair of spacers 48 is formed along the sidewalls of the gate dielectric 44 and gate electrode 46. The spacers 48 may be formed by well-known methods such as blanket or selectively depositing a dielectric layer over regions including substrate 10 and gate electrode 46, then anisotropically etching to remove the dielectric layer from the horizontal surfaces and leaving spacers 48.

While active devices are formed in active regions, dummy patterns are simultaneously formed in dummy active regions. FIG. 6 illustrates a dummy gate that comprises a dummy gate electrode 47, dummy gate dielectric 45 and dummy spacers 49. Dummy gates help to reduce pattern-loading effects such as dishing effects in subsequent chemical mechanical polish steps.

FIG. 6 also shows a pair of recesses 50 formed adjacent to spacers on either side of the gate electrode 46 by etching into substrate 10. In the preferred embodiment, substrate 10 is undercut beneath spacers 48, resulting in the recesses being substantially aligned with gate electrode 46. Spacers 48 are designed so as to allow for precise alignment of the recesses with the gate electrodes. Recesses 50 may be formed by anisotropically etching the substrate using, e.g., ion etching. Anisotropic etching causes the recesses to be formed in the region not protected by spacers. It has to be realized that there also exists lateral etching, causing the recesses to extend below the spacers. The width of the spacer 48 forms a region that allows some room for lateral etching. Through remaining openings 38 in the dummy active region, substrate 10 is also etched in the dummy active region, preferably simultaneously with the etching of openings 50.

FIG. 7 illustrates source and drain regions 52 and dummy features 54 selectively grown in recesses 50 by selective epitaxial growth (SEG). The material of source and drain regions 52 and dummy features 54 is a semiconductor, and desired impurities may be doped while the growth proceeds. Typically, if openings 38 are not formed, the growth rate in a densely patterned region, such as the center of the active region 20, will be less than the growth rate in sparsely patterned region, such as the edge of the active region 20. The composition of the resulting material, such as the doping concentration at the center and at the edges of the active region, will also be different. With the selective epitaxial growth in the openings 38, the pattern density is more uniform, the pattern-loading effect is reduced, and the process of selective growth is better controlled.

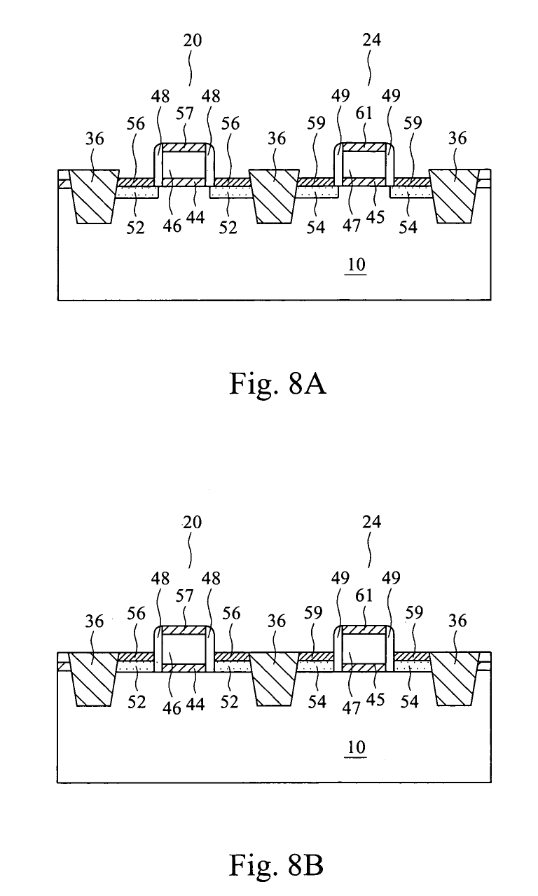

FIG. 8A illustrates silicides 56 and dummy silicides 59 formed over source and drain regions 52 and dummy features 54, respectively, and silicide 57 and dummy silicide 61 formed over the gate electrode 46 and dummy gate electrode 47, respectively. In a preferred embodiment, silicides 56 and dummy suicides 59 are metal silicides formed by first depositing a thin layer of metal, such as titanium, cobalt, nickel, tungsten, or the like, over the device, including the exposed surfaces of source and drain regions 52 and gate electrode 46 (and dummy gate electrode 47). The device is then heated, which causes the silicide reaction to occur wherever the metal is in contact with the silicon. After reaction, a layer of metal silicide is formed between the exposed silicon and metal. The un-reacted metal is selectively removed through the use of an etchant that does not attack the silicide, SiO₂ and silicon substrate.

In alternative embodiments, source and drain regions 52 and dummy features 54 are selectively grown on the substrate 10. FIG. 8B illustrates an embodiment having raised source/drain regions 52 and dummy features 54. Similar to the preferred embodiment, the source/drain regions 52 and dummy features 54 are semiconductor material deposited by selective epitaxial growth.

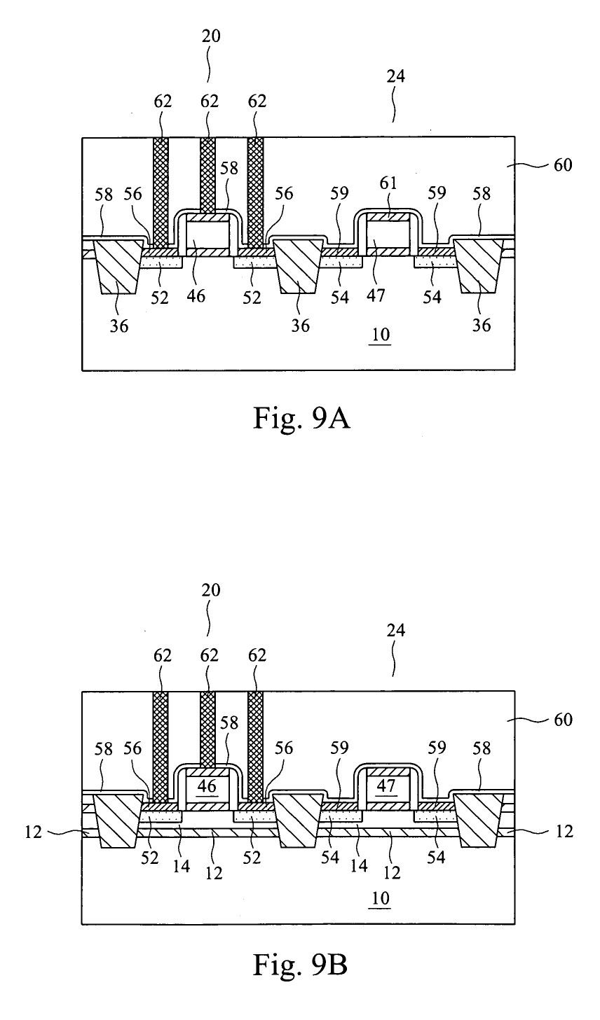

In, FIG. 9A, an etch stop layer (ESL) 58 is blanket deposited over the device. ESL 58 may be formed using low-pressure chemical vapor deposition (LPCVD), but other CVD methods, such as plasma enhanced chemical vapor deposition (PECVD), and thermal CVD may also be used. An inter-level dielectric (ILD), also sometimes known as a pre-metal dielectric (PMD) or an inter-metal dielectric (IMD) layer is next deposited over the surface of the structure formed in previous steps. This ILD layer 60 is preferably a low-k material or a silicon dioxide deposited using, e.g., Tetraethyl orthosilicate (TEOS), CVD, PECVD, LPCVD, or other well-known deposition techniques. The ILD layer 60 provides insulation between the transistor and overlying metal lines. The dummy gate electrode 47, dummy silicides 56 and dummy features 54 are covered by ESL 58 and ILD layer 60 and are thus isolated from the rest of the devices in the circuit. A photo-resist material (not shown) may be formed and patterned over the ILD layer 60 in order to form contact openings to the source and drain regions 52 and gate electrode 46. ESL 58 operates as an etch stop layer during the etching of ILD layer 60 and thus protects the underlying silicide layer 57/59. Additionally, process control and end-point detection are more closely controlled, thus limiting the likelihood of over-etching through the underlying silicide layer 57/59. Contact plugs 62 are then formed providing access to the source/drain 52 and gate electrode 46 of the device in the active region. In the dummy active region, no contact plugs need to be formed.

There are several variations of the preferred embodiments of the present invention. In one variation, as shown in FIG. 9B, the substrate has an SOI structure such as shown in FIG. 1B. While source and drain regions 52 are formed, selective growth also occurs on the second substrate 14 in the dummy active region 24. The openings 38 are formed in the dummy active region, exposing the second substrate 14. Selective epitaxial growth occurs on the second substrate 14 in both the active region 20 and dummy active region 24. In another variation, additional openings 38 for dummy features can also be formed in active regions where the device density is low. This improves pattern density uniformity within the active region and further reduces the pattern-loading effect. In yet other variations, the concept of opening the existing dielectric layer to expose the substrate and achieve a uniform pattern loading effect for selective epitaxial growth is not limited to the growth of source and drain regions. It can be used on any epitaxial growth processes.

The present invention uses existing structures to reduce the pattern loading effect of semiconductor processes. Uniform EPI thickness and composition at both isolated and densely packed active areas are achieved. In the preferred embodiments of the present invention, the openings for the dummy features are formed simultaneously with the formation of devices. Therefore, no extra process is needed.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a semiconductor structure, the method comprising:
forming a mask layer over a substrate;
forming an isolation region in the substrate isolating an active region and a dummy active region;
removing at least a portion of the mask layer in the active region and thus forming a first opening, the substrate being exposed through the first opening;
removing at least a portion of the mask layer in the dummy active region and thus forming a second opening, the substrate being exposed through the second opening; and
performing a selective epitaxial growth simultaneously on the substrate in the first opening and second opening.

2. The method of claim 1 wherein the first and second openings are formed simultaneously.

3. The method of claim 1 wherein the step of forming the isolation region comprises:
forming a trench in the substrate;
filling the trench with a dielectric material; and
removing excess dielectric material.

4. The method of claim 1 further comprising the step of forming a pad layer between the substrate and the mask layer.

5. The method of claim 1 wherein the performing selective epitaxial growth step forms a source region and a drain region in the active region and wherein the method further comprises the steps of:
forming a gate dielectric over the substrate between the source region and the drain region;
forming a gate electrode over the gate dielectric; and
forming a pair of spacers along opposite sidewalls of the gate electrode and the gate dielectric.

6. The method of claim 1 further comprising forming a third opening in the active region, wherein the selective epitaxial growth is performed in the third opening simultaneously as in the first and second openings, and wherein no device is formed in the third opening.

7. The method of claim 1 wherein the substrate comprises:
a first substrate;
a buried oxide layer over the first substrate; and
a second substrate having a thickness over the buried oxide layer, wherein the isolation region has a depth greater than the thickness of the second substrate.

8. A method of forming a semiconductor structure, the method comprising:
forming a mask layer over a substrate;
forming an isolation region in the substrate isolating an active region and a dummy active region;
removing at least a portion of the mask layer in the active region and thus forming a first opening, the substrate being exposed through the first opening;
removing at least a portion of the mask layer in the dummy active region and thus forming a second opening, the substrate being exposed through the second opening;
forming a gate dielectric over the substrate in the first opening;
forming a gate electrode over the gate dielectric;
forming a spacer along a sidewall of the gate electrode and the gate dielectric; and
performing a selective epitaxial growth in the first opening to form a source/drain region substantially aligned with an edge of the spacer wherein the selective epitaxial growth is simultaneously performed in the second opening.

9. The method of claim 8 wherein the first and second openings are formed simultaneously.

10. The method of claim 8 wherein the step of forming the isolation region comprises:
forming a trench in the substrate;
filling the trench with a dielectric material; and
removing excess dielectric material.

11. The method of claim 8 further comprising the step of forming a pad layer between the substrate and the mask layer.

12. The method of claim 8 wherein the substrate comprises:
a first substrate;
a buried oxide layer over the first substrate; and
a second substrate having a thickness over the buried oxide layer, wherein the isolation region has a depth greater than the thickness of the second substrate.

13. A semiconductor structure comprising:
a mask layer over a substrate;
an isolation region in the substrate isolating an active region and a dummy active region;
a gate dielectric over the substrate in the active region;
a gate electrode over the gate dielectric;
a source/drain region substantially aligned with an edge of the gate electrode; and
a first semiconductor dummy feature in the dummy active region and not electrically coupled to active devices, the semiconductor dummy feature having a composition substantially the same as the source/drain region.

14. The semiconductor structure of claim 13 wherein the first semiconductor dummy feature is physically in contact with the substrate.

15. The semiconductor structure of claim 13 wherein the first semiconductor dummy feature and the source/drain region have substantially similar thickness.

16. The semiconductor structure of claim 13 further comprising a second semiconductor dummy feature in the active region and not electrically coupled to the active devices.
